(19) United States
(12) Patent Application Publication
(10) Pub. No.: US 2026/0023099 A1
(43) Pub. Date: Jan. 22, 2026

(54) TEST SYSTEM AND METHOD FOR PERFORMING HIGH-VOLTAGE TESTING ON A DEVICE UNDER TEST

(71) Applicant: MPI CORPORATION, CHU-PEI CITY (TW)

(72) Inventor: CHIA-CHING WANG, CHU-PEI CITY (TW)

(73) Assignee: MPI CORPORATION, CHU-PEI CITY (TW)

(21) Appl. No.: 19/262,447

(22) Filed: Jul. 8, 2025

Related U.S. Application Data
(60) Provisional application No. 63/673,322, filed on Jul. 19, 2024.

(51) Int. Cl. G01R 1/07; G01R 1/067; G01R 1/073

(52) U.S. Cl. CPC G01R 1/072; G01R 1/06777; G01R 1/07342

(57) ABSTRACT

A test system and method for performing high-voltage testing on a device under test (DUT), which provides a gas monitoring device and a control unit of the test system. The high-voltage test probe card system is equipped with synchronized pressure and flow monitoring functionality. A pressure and flow sensor is arranged upstream of a gas space of a probe card assembly, in coordination with the gas monitoring device and the control unit of the test system, thereby forming a complete and closed-loop control mechanism.

### BACKGROUND OF THE INVENTION

### 1. Field of the Invention

The present invention relates to a test system and a test method for performing high-voltage testing on a device under test and more particular, to a high-voltage testing probe card system that provides a gas monitoring device and a control unit of the testing system, enabling synchronous monitoring of gas pressure and flow rate.

### 2. Description of the Related Art

In the current high-voltage (HV) probe card testing technology used for high-voltage testing of a device under test (DUT), in order to prevent high-voltage discharge, such as arcing, between probes of the high-voltage probe card during testing, which may damage the probe card and/or the DUT, a sealed chamber is typically established between the probe area and the DUT. High-pressure gas is injected into the chamber to enhance the gas insulation effect. However, in the industry, pressure monitoring devices are mostly installed only at the gas supply end, and there is a lack of real-time detection and control mechanisms for the actual gas pressure changes within the chamber. Please refer to FIG. 8, which is a schematic diagram of a conventional technique where a high-voltage probe card performs high-voltage testing on a device under test. As shown in the figure, an external gas supply device B′ (or the gas source end) provides a high-pressure gas which flows through a regulating valve 4′ into a gas space 142′ (inside the sealed chamber). However, the high-pressure gas is monitored only at the gas supply end, while the actual gas pressure inside the gas space 142′ (in the sealed chamber) remains unknown. Furthermore, the flow rate of the high-pressure gas is not monitored either, even though flow rate affects the speed at which pressure builds up inside the gas space 142′. On the other hand, excessive flow rate can negatively impact the stability of the probes. Therefore, how to get a balance between the two non-proportional factors, pressure and flow rate, so that the probes can stably contact the DUT and avoid arcing caused by excessive voltage, thereby ensuring probe stability, is a problem that the present invention aims to solve.

### SUMMARY OF THE INVENTION

The primary objective of the present invention, which relates to a testing system and testing method for high-voltage testing of a device under test, is to provide a gas monitoring device disposed between an external gas supply device and a probe card assembly, thereby forming a high-voltage testing probe card system with the capability to synchronously monitor both pressure and flow rate. When the gas pressure value of gas entering a gas space of the probe card assembly is not less than a gas pressure set value, and the gas flow rate value is not greater than a gas flow rate set value, a signal is output to a control unit. This allows a high-voltage test signal to be transmitted via the probe card assembly to the probes of the probe card assembly, thereby enabling the test apparatus or equipment to perform electrical testing on the device under test.

Furthermore, the variation in gas flow rate has not been effectively considered and addressed in the prior arts. Neglecting flow rate may lead to two issues: 1. slow pressure buildup: If the gas flow rate is too low, it will delay the gas pressure from reaching the set value, thereby prolonging the waiting time of the testing process; and 2. probe instability: If the gas flow rate is too high, it may cause excessive turbulence within the chamber, leading to probe disturbance, which in turn affects measurement stability and accuracy. Due to the inability to simultaneously control and determine the real-time status of both gas pressure and flow rate, conventional systems are prone to the risk of initiating testing before conditions are properly met, thus increasing the likelihood of probe damage or test failure. Accordingly, the primary objective of the present invention, which relates to another testing system and testing method for high-voltage testing of a device under test, is to provide a gas monitoring device disposed between an external gas supply device and a probe card assembly, thereby forming a high-voltage testing probe card system with the capability to synchronously monitor both pressure and flow rate. When the controller and the sensor interact and detect that the gas flow rate value is not greater than a gas flow rate set value, a signal is output to a control unit. This allows a high-voltage test signal to be transmitted via the probe card assembly to the probes of the probe card assembly, thereby enabling the test apparatus or equipment to perform electrical testing on the device under test. Through this approach, the invention achieves the effects of shortening the waiting time of the test process and stabilizing the probes. A test system for performing high-voltage testing on a device under test, the test system comprising:
a probe card assembly, comprising:
   a cover body;
   an annular structure having a top surface disposed below the cover body, at least one vent hole in fluid communication with the cover body, a gas space, and a bottom surface configured for facing the device under test; a gas outlet being located below the bottom surface; and
   at least one probe electrically connected with the cover body, accommodated within the gas space, and extending out of the gas space for electrical contact with the device under test during testing;
a gas monitoring device, comprising:
   a controller;
   a sensor in fluid communication with the cover body and electrically connected with the controller; and
   a regulating valve having an end connected with the sensor and the other end in fluid communication with an external gas supply device;
a test apparatus electrically connected with the controller and configured for accommodating the device under test; and
a control unit electrically connected with the gas monitoring device and the test apparatus;
wherein a gas is provided from the external gas supply device, flows through the regulating valve, then to the sensor, and into the cover body, enters the at least one vent hole of the annular structure, then into the gas space, passes through the at least one probe disposed in the gas space, and exits via the gas outlet;
wherein when the controller interacts with the sensor to detect that a gas pressure value detected by the sensor and a gas pressure set value and/or a gas flow rate value detected by the sensor and a gas flow rate set value exhibit a plurality of variation relationships, the probe card assembly, the gas monitoring device, the test apparatus, and the control unit perform corresponding testing operations based on the plurality of variation relationships.

A test method for performing high-voltage testing on a device under test, the method comprising the following steps:
(SA) providing a gas from an external gas supply device;
(SB) directing the gas to a regulating valve of a gas monitoring device;
(SC) directing the gas to a sensor of the gas monitoring device;
(SD) directing the gas to a cover body of a probe card assembly;
(SE) directing the gas to at least one vent hole of an annular structure of the probe card assembly, wherein a top surface of the annular structure is disposed below the cover body;
(SF) directing the gas to a gas space of the annular structure of the probe card assembly, such that the gas flows through at least one probe disposed in the gas space;
(SG) directing the gas to a gas outlet of the annular structure, such that the gas is discharged from the gas outlet, wherein the gas outlet is located below a bottom surface of the annular structure;
(SH) interacting a controller of the gas monitoring device with the sensor to detect that a gas pressure value and a gas pressure set value and/or a gas flow rate value and a gas flow rate set value exhibit a plurality of variation relationships; and
(SI) performing corresponding testing operations based on the plurality of variation relationships by the probe card assembly, the gas monitoring device, the control unit, and the test apparatus.

A gas monitoring device applied in a high-voltage test system for testing a device under test, to monitor and control a gas pressure value and a gas flow rate value of a gas supplied to a probe card assembly, the gas monitoring device comprising:
a controller;
a sensor connected with the probe card assembly and electrically connected with the controller, to detect the gas pressure value and the gas flow rate value, to generate a pressure signal and a flow rate signal, and to transmit the pressure signal and the flow rate signal to the controller;
a regulating valve having an end connected with the sensor and the other end in fluid communication with an external gas supply device which supplies the gas to the regulating valve;
wherein, when the controller interacts with the sensor to detect that the gas pressure value is not less than a gas pressure set value, and the gas flow rate value is not greater than a gas flow rate set value, the controller outputs a control/drive signal to a control unit of the test system, enabling the probe card assembly to transmit a high-voltage test signal to perform electrical testing on the device under test.

A gas monitoring method applied in a test system for high-voltage testing of device under test, to monitor and control a gas pressure value and a gas flow rate value of a gas supplied to a probe card assembly, the gas monitoring method comprising the following steps:
(SX1) supplying the gas from an external gas supply device to a regulating valve;
(SX2) regulating a pressure and a flow rate of the gas by the regulating valve and directing the gas to a sensor;
(SX3) outputting the gas by the sensor to the probe card assembly;
(SX4) detecting the gas pressure value and the gas flow rate value and generating a pressure signal and a flow rate signal by the sensor;
(SX5) transmitting the pressure signal and the flow rate signal to the controller, and interacting the controller with the sensor to detect that the gas pressure value is not less than a gas pressure set value, and the gas flow rate value is not greater than a gas flow rate set value; and
(SX6) outputting a control/drive signal to a control unit of the test system, enabling the probe card assembly to transmit a high-voltage test signal to perform electrical testing on the device under test.

Further scope of applicability of the present invention will become apparent from the detailed description given hereinafter. However, it should be understood that the detailed description and specific examples, while indicating preferred embodiments of the invention, are given by way of illustration only, since various changes and modifications within the scope of the invention will become apparent to those skilled in the art from this detailed description.

### BRIEF DESCRIPTION OF THE DRAWINGS

The present invention will become more fully understood from the detailed description given herein below and the accompanying drawings which are given by way of illustration only, and thus are not limitative of the present invention, and wherein:

FIG. 1 is a modular schematic diagram of a test system for high-voltage testing of a device under test according to the present invention;

FIG. 2 is a structural sectional view of a probe card assembly according to the present invention;

FIG. 3 is an exploded perspective view of the probe card assembly according to the present invention;

FIG. 4 is a perspective view of an annular structure of the probe card assembly according to the present invention;

FIG. 5 is a step diagram of a test method for high-voltage testing of a device under test according to the present invention;

FIG. 5A is a step diagram of a first variation relationship among a plurality of variation relationships between a gas pressure value and a gas pressure set value and/or between a gas flow rate value and a gas flow rate set value in the test method for high-voltage testing of the device under test according to the present invention;

FIG. 5B is a step diagram of a second variation relationship among a plurality of variation relationships between a gas pressure value and a gas pressure set value and/or between a gas flow rate value and a gas flow rate set value in the test method for high-voltage testing of the device under test according to the present invention;

FIG. 5C is a step diagram of a third variation relationship among a plurality of variation relationships between a gas pressure value and a gas pressure set value and/or between a gas flow rate value and a gas flow rate set value in the test method for high-voltage testing of the device under test according to the present invention;

FIG. 5D is a step diagram of a fourth variation relationship among a plurality of variation relationships between a gas pressure value and a gas pressure set value and/or between a gas flow rate value and a gas flow rate set value in the test method for high-voltage testing of the device under test according to the present invention;

FIG. 5E is a step diagram of a fifth variation relationship among a plurality of variation relationships between a gas pressure value and a gas pressure set value and/or between a gas flow rate value and a gas flow rate set value in the test method for high-voltage testing of the device under test according to the present invention;

FIG. 5F is a step diagram of a sixth variation relationship among a plurality of variation relationships between a gas pressure value and a gas pressure set value and/or between a gas flow rate value and a gas flow rate set value in the test method for high-voltage testing of the device under test according to the present invention;

FIG. 5G is a step diagram of a seventh variation relationship among a plurality of variation relationships between a gas pressure value and a gas pressure set value and/or between a gas flow rate value and a gas flow rate set value in the test method for high-voltage testing of the device under test according to the present invention;

FIG. 5H is a step diagram of an eighth variation relationship among a plurality of variation relationships between a gas pressure value and a gas pressure set value and/or between a gas flow rate value and a gas flow rate set value in the test method for high-voltage testing of the device under test according to the present invention;

FIG. 6 is a module diagram illustrating the method of the present invention for high-voltage testing of the device under test, wherein the opening degree of the regulating valve is automatically adjusted in a closed-loop manner;

FIG. 7 is a step diagram of the gas monitoring method of the test system for high-voltage testing of the device under test according to the present invention; and

FIG. 8 is a schematic diagram of a conventional technique in which a high-voltage probe card performs high-voltage testing on a device under test.

### DETAILED DESCRIPTION OF THE INVENTION

The technical content and features of the present invention will be described in detail in conjunction with the drawings through one or more embodiments described below, which are not intended to limit the scope of the present disclosure. In addition, the drawings are provided for illustrative purposes only and are not drawn to scale. For ease of understanding, the same reference numerals are used to identify identical elements in the following description.

The terms such as “comprise,” “include,” and “have” mentioned in the present disclosure are open-ended terms, which mean “including but not limited to.”

In the description of various embodiments, terms such as “first,” “second,” “third,” “fourth,” etc., are merely used to distinguish the elements from one another and do not imply any order or importance.

In the description of various embodiments, the terms “coupled” or “connected” may refer to two or more elements being in direct physical or electrical contact with each other, or being in indirect physical or electrical contact with each other. Moreover, “coupled” or “connected” may also refer to two or more elements being functionally associated or interacting with each other.

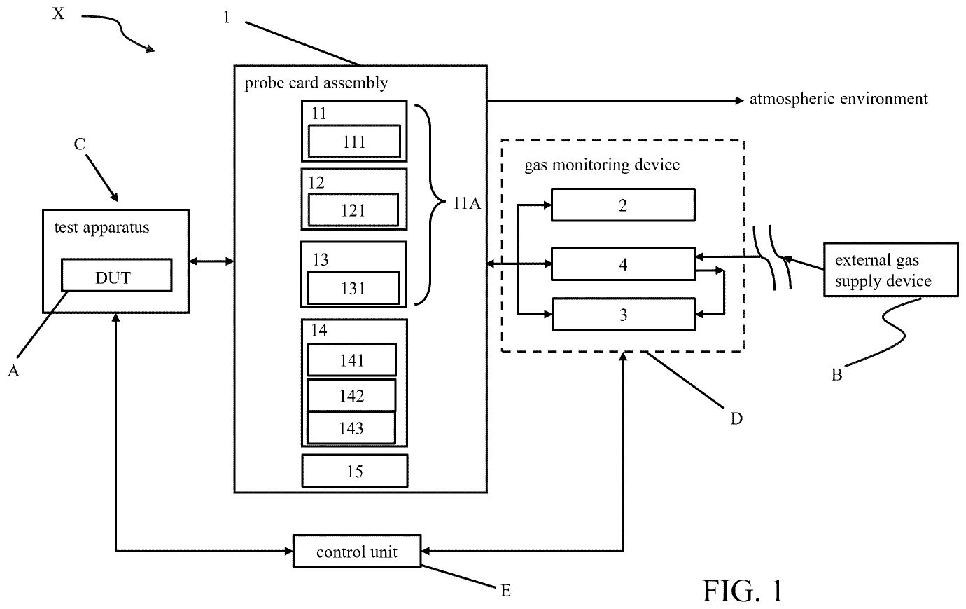

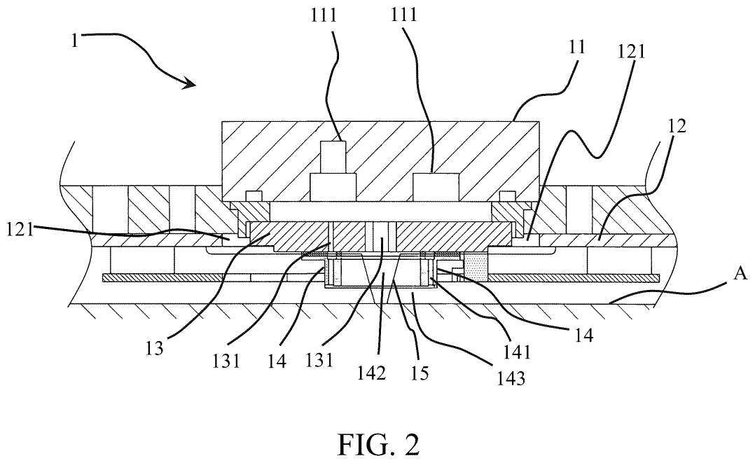

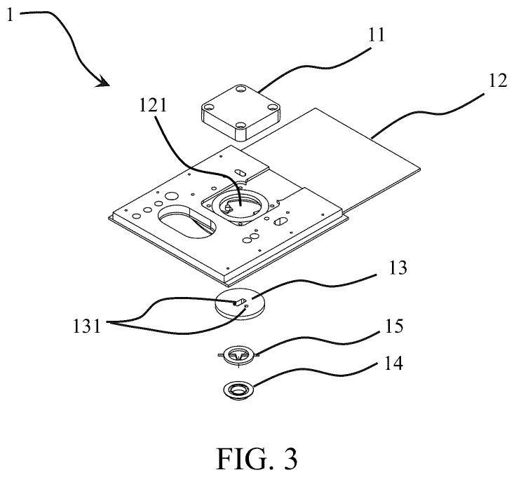

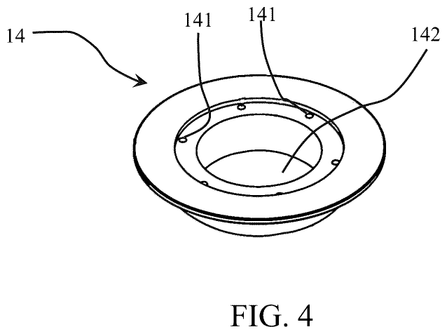

Please refer to FIGS. 1-4, which respectively illustrate a modular schematic diagram of a test system for high-voltage testing of a device under test according to the present invention, a structural sectional view of a probe card assembly, an exploded perspective view of the probe card assembly, and a perspective view of an annular structure of the probe card assembly. The high-voltage test system X includes: a probe card assembly 1, comprising: a cover body 11A; an annular structure 14 having a top surface disposed below the cover body 11A, at least one vent hole 141 in fluid communication with the cover body 11A, a gas space 142, and a bottom surface configured for facing a device under test A; a gas outlet 143 being located below the bottom surface; and at least one probe 15 electrically connected with the cover body 11A, accommodated within the gas space 142, and extending out of the gas space 142 for electrical contact with the device under test A during testing;

a gas monitoring device D, comprising: a controller 2; a sensor 3 in fluid communication with the cover body 11A and electrically connected with the controller 2; and a regulating valve 4 having an end connected with the sensor 3 and the other end in fluid communication with an external gas supply device B;

a test apparatus C electrically connected with the controller 2 and configured for accommodating the device under test A; and

a control unit E electrically connected with the gas monitoring device D and the test apparatus C;

wherein a gas is provided from the external gas supply device B, flows through the regulating valve 4, then to the sensor 3, and into the cover body 11A, enters the at least one vent hole 141 of the annular structure 14, then into the gas space 142, passes through the at least one probe 15 disposed in the gas space 142, and exits via the gas outlet 143.

When the controller 2 interacts with the sensor 3 to detect/determine that a gas pressure value detected by the sensor 3 and a gas pressure set value and/or a gas flow rate value detected by the sensor 3 and a gas flow rate set value exhibit a plurality of variation relationships, the probe card assembly 1, the gas monitoring device D, the test apparatus C, and the control unit E perform corresponding testing operations based on the plurality of variation relationships.

Thus, when the controller 2 interacts with the sensor 3 to detect/determine that the gas pressure value is not less than the gas pressure set value, and the gas flow rate value is not greater than the gas flow rate set value, the controller 2 outputs a control signal to the control unit E, enabling that a high-voltage test signal is transmitted via the probe card assembly 1 to the probe 15, thereby driving the test apparatus C to perform electrical testing on the device under test A. The high-voltage testing referred to in the present invention means testing at voltages above 2000 volts.

After the gas flows into the annular structure 14, it exits through the gas outlet 143 located below the bottom surface of the annular structure 14. During high-voltage testing, the probe card assembly 1 and the device under test A are approached to each other, causing the probe 15 of the probe card assembly 1 to make contact with the device under test A. At this time, the gas outlet 143 is located between the bottom surface of the annular structure 14 and the device under test A.

Furthermore, the cover body 11A includes: a gas supply connection plate 11 having a guide hole 111; a wiring board 12 having a through hole 121; and a top cover 13 having an inlet hole 131. The gas supply connection plate 11 is disposed above the wiring board 12, the top cover 13 is disposed below the gas supply connection plate 11, and the top cover 13 is embedded within the wiring board 12 and disposed in the through hole 121. The gas supply connection plate 11 is used to connect the gas monitoring device D. The wiring board 12 is electrically connected with the at least one probe 15. The top surface of the annular structure 14 is disposed below the top cover 13. The gas supplied from the external gas supply device B flows through the sensor 3, then through the guide hole 111 of the gas supply connection plate 11, and into the inlet hole 131 of the top cover 13.

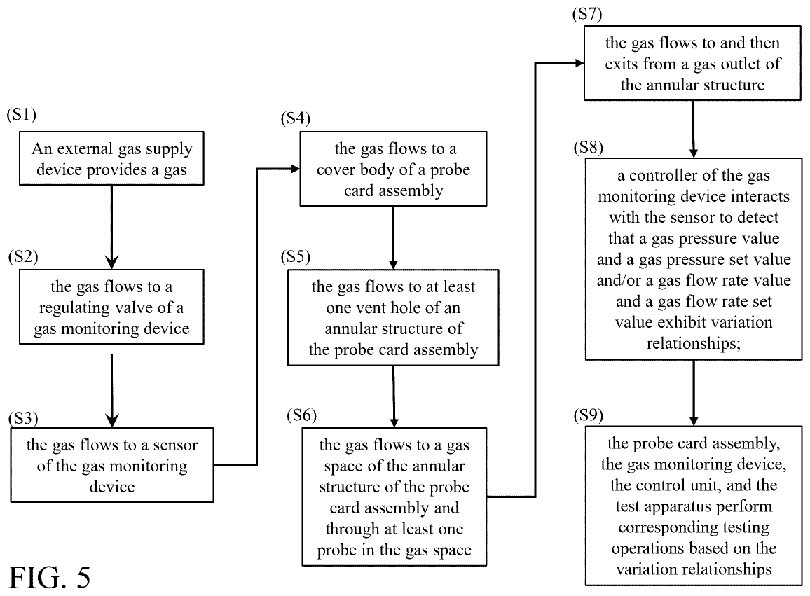

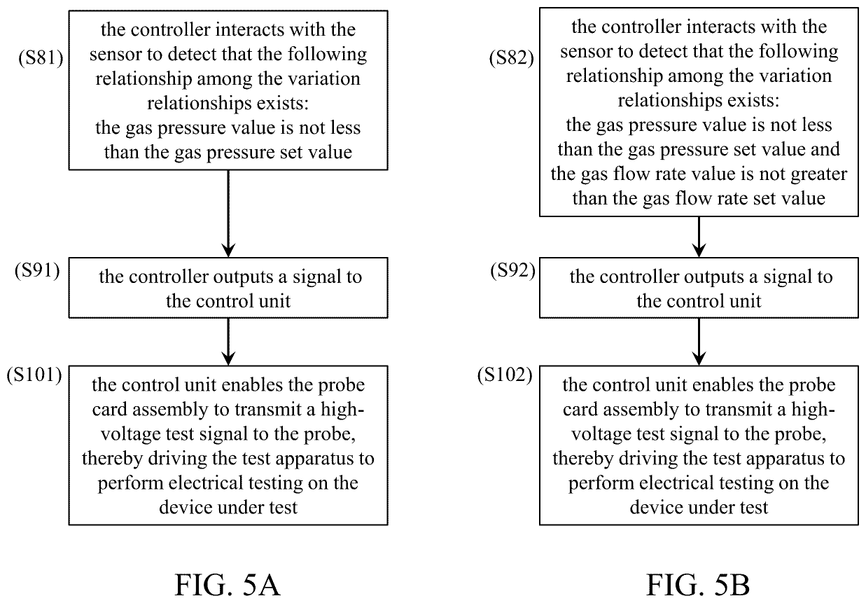

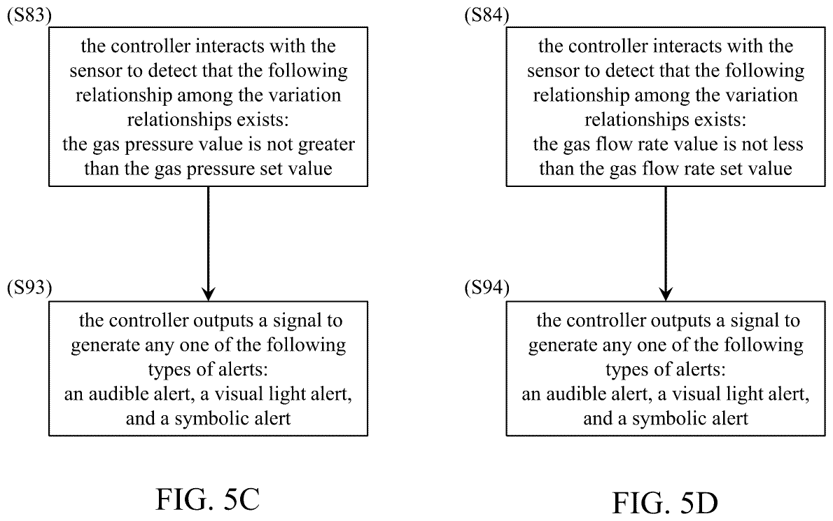

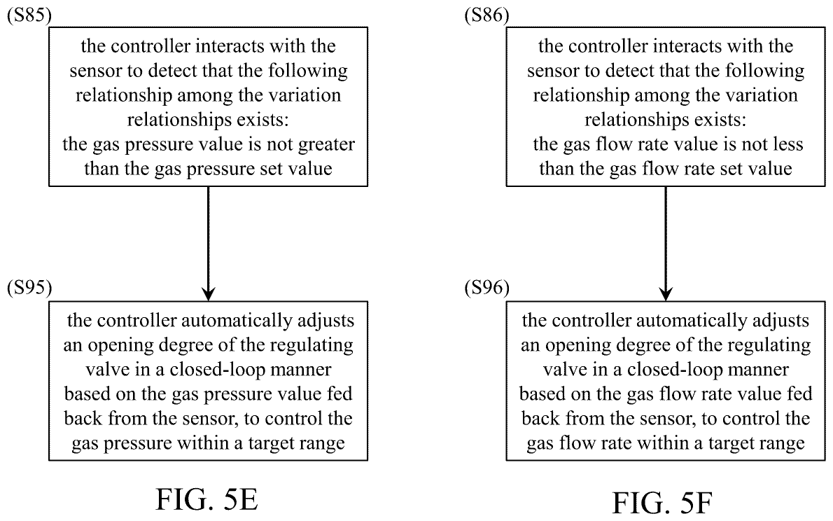

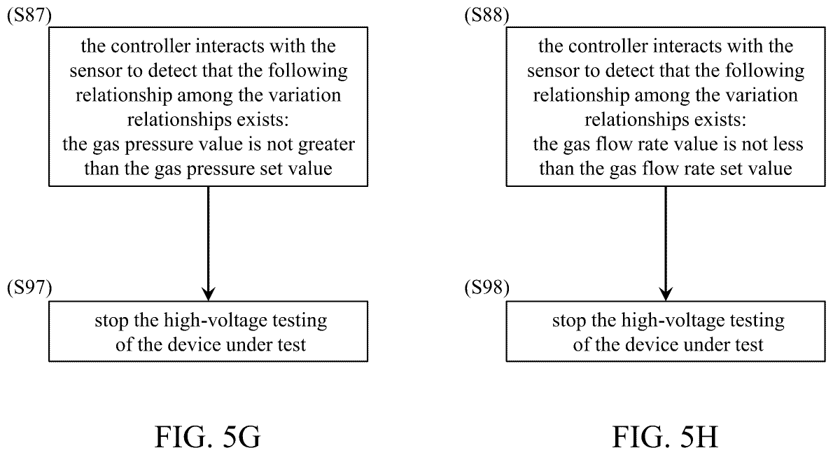

Please refer to FIG. 5, which illustrates a step diagram of a test method for high-voltage testing of a device under test according to the present invention. The method comprises the following steps:
(S1) providing a gas via an external gas supply device B;
(S2) directing the gas to a regulating valve 4 of a gas monitoring device D;
(S3) directing the gas to a sensor 3 of the gas monitoring device D;
(S4) directing the gas to a cover body 11A of a probe card assembly 1;
(S5) directing the gas to at least one vent hole 141 of an annular structure 14 of the probe card assembly 1, wherein a top surface of the annular structure 14 is disposed below the cover body 11A;
(S6) directing the gas to a gas space 142 of the annular structure 14 of the probe card assembly 1, such that the gas flows through at least one probe 15 disposed in the gas space 142;
(S7) directing the gas to a gas outlet 143 of the annular structure 14, such that the gas is discharged from the gas outlet 143, wherein the gas outlet 143 is located between the bottom surface of the annular structure 14 and the device under test A;
(S8) interacting a controller 2 of the gas monitoring device D with the sensor 3 to detect/determine that a gas pressure value and a gas pressure set value and/or a gas flow rate value and a gas flow rate set value exhibit a plurality of variation relationships; and
(S9) performing corresponding testing operations based on the plurality of variation relationships by the probe card assembly 1, the gas monitoring device D, the control unit E, and the test apparatus C.

Please refer to FIG. 5A, which illustrates a step diagram of a first variation relationship among a plurality of variation relationships between a gas pressure value and a gas pressure set value and/or between a gas flow rate value and a gas flow rate set value in the test method for high-voltage testing of the device under test according to the present invention. Steps (S8) to (S9) further include the following steps:
(S81) interacting the controller 2 with the sensor 3 to detect/determine that the following relationship among the plurality of variation relationships exists: the gas pressure value is not less than the gas pressure set value;
(S91) outputting a signal by the controller 2 to the control unit E; and
(S101) enabling the probe card assembly 1 by the control unit E to transmit a high-voltage test signal to the probe 15, thereby driving the test apparatus C to perform electrical testing on the device under test A.

The controller 2 further includes a built-in table comprising: a tip pitch dataset of the probe 15, a temperature dataset of the device under test A, a high-voltage testing dataset, and a recommended pressure value dataset. The recommended pressure value dataset corresponds to the tip pitch dataset of the probe 15, the temperature dataset of the device under test A, and the high-voltage testing dataset. The built-in table of the controller 2 is used for an automated testing function of the test system. When the test system performs the automated testing function, the datasets in the built-in table are used to judge suggested pressure values that are required for use, to determine the gas pressure set value. Additionally, the controller 2 further includes an input interface that allows a user to manually input a gas pressure set value, thereby enabling the manual testing function of the test system.

Please refer to FIG. 5B, which illustrates a step diagram of a second variation relationship among a plurality of variation relationships between a gas pressure value and a gas pressure set value and/or between a gas flow rate value and a gas flow rate set value in the test method for high-voltage testing of the device under test according to the present invention. Steps (S8) to (S9) further include the following steps:
(S82) interacting the controller 2 with the sensor 3 to detect/determine that the following relationship among the plurality of variation relationships exists: the gas pressure value is not less than the gas pressure set value and the gas flow rate value is not greater than the gas flow rate set value;
(S92) outputting a signal by the controller 2 to the control unit E; and
(S102) enabling the probe card assembly 1 by the control unit E to transmit the high-voltage test signal to the probe 15, thereby driving the test apparatus C to perform electrical testing on the device under test A.

The controller 2 further includes the built-in table, comprising: the tip pitch dataset of the probe 15, the temperature dataset of the device under test A, the high-voltage testing dataset, and a recommended pressure and flow rate dataset. The recommended pressure and flow rate dataset corresponds to the tip pitch dataset of the probe 15, the temperature dataset of the device under test A, and the high-voltage testing dataset. The built-in table of the controller 2 is used for an automated testing function of the test system. When the test system performs the automated testing function, the datasets in the built-in table are used to judge suggested pressure and flow rate values that are required for use, to determine the gas pressure set value and the gas flow rate set value. Additionally, the controller 2 further includes an input interface that allows a user to manually input a gas pressure set value and a gas flow rate set value, thereby enabling the manual testing function of the test system.

Please refer to FIG. 5C, which illustrates a step diagram of a third variation relationship among a plurality of variation relationships between a gas pressure value and a gas pressure set value and/or between a gas flow rate value and a gas flow rate set value in the test method for high-voltage testing of the device under test according to the present invention. Steps (S8) to (S9) further include the following steps:
(S83) interacting the controller 2 with the sensor 3 to detect/determine that the following relationship among the plurality of variation relationships exists: the gas pressure value is not greater than the gas pressure set value; and
(S93) outputting a signal by the controller 2 to generate any one of the following types of alerts: an audible alert, a visual light alert, and a symbolic alert.

The controller 2 further includes a built-in table comprising: the tip pitch dataset of the probe 15, the temperature dataset of the device under test A, the high-voltage testing dataset, and the recommended pressure value dataset. The recommended pressure value dataset corresponds to the tip pitch dataset of the probe 15, the temperature dataset of the device under test A, and the high-voltage testing dataset.

Please refer to FIG. 5D, which illustrates a step diagram of a fourth variation relationship among a plurality of variation relationships between a gas pressure value and a gas pressure set value and/or between a gas flow rate value and a gas flow rate set value in the test method for high-voltage testing of the device under test according to the present invention. Steps (S8) to (S9) further include the following steps:
(S84) interacting the controller 2 with the sensor 3 to detect that the following relationship among the plurality of variation relationships exists: the gas flow rate value is not less than the gas flow rate set value; and
(S94) outputting a signal by the controller 2 to generate any one of the following types of alerts: an audible alert, a visual light alert, and a symbolic alert.

Please refer to FIG. 5E, which illustrates a step diagram of a fifth variation relationship among a plurality of variation relationships between a gas pressure value and a gas pressure set value and/or between a gas flow rate value and a gas flow rate set value in the test method for high-voltage testing of the device under test according to the present invention. Steps (S8) to (S9) further include the following steps:
(S85) interacting the controller 2 with the sensor 3 to detect/determine that the following relationship among the plurality of variation relationships exists: the gas pressure value is not greater than the gas pressure set value; and
(S95) adjusting automatically an opening degree of the regulating valve 4 by the controller 2 in a closed-loop manner based on the gas pressure value fed back from the sensor 3, to control the gas pressure within a target range.

Please refer to FIG. 5F, which illustrates a step diagram of a sixth variation relationship among a plurality of variation relationships between a gas pressure value and a gas pressure set value and/or between a gas flow rate value and a gas flow rate set value in the test method for high-voltage testing of the device under test according to the present invention. Steps (S8) to (S9) further include the following steps:
(S86) interacting the controller 2 with the sensor 3 to detect/determine that the following relationship among the plurality of variation relationships exists: the gas flow rate value is not less than the gas flow rate set value; and
(S96) adjusting automatically the opening degree of the regulating valve 4 by the controller 2 in a closed-loop manner based on the gas flow rate value fed back from the sensor 3, to control the gas flow rate within a target range.

Please refer to FIG. 5G, which illustrates a step diagram of a seventh variation relationship among a plurality of variation relationships between a gas pressure value and a gas pressure set value and/or between a gas flow rate value and a gas flow rate set value in the test method for high-voltage testing of the device under test according to the present invention. Steps (S8) to (S9) further include the following steps:
(S87) interacting the controller 2 with the sensor 3 to detect/determine that the following relationship among the plurality of variation relationships exists: the gas pressure value is not greater than the gas pressure set value; and
(S97) stopping the high-voltage testing of the device under test.

Please refer to FIG. 5H, which illustrates a step diagram of an eighth variation relationship among a plurality of variation relationships between a gas pressure value and a gas pressure set value and/or between a gas flow rate value and a gas flow rate set value in the test method for high-voltage testing of the device under test according to the present invention. Steps (S8) to (S9) further include the following steps:
(S88) interacting the controller 2 with the sensor 3 to detect/determine that the following relationship among the plurality of variation relationships exists: the gas flow rate value is not less than the gas flow rate set value; and
(S98) stopping the high-voltage testing of the device under test.

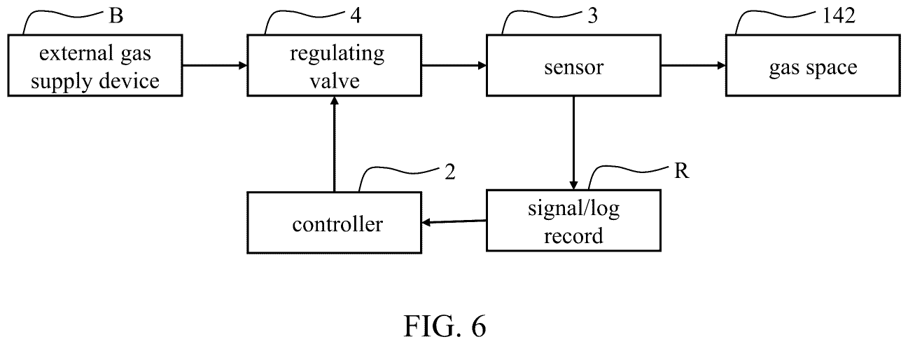

Please refer to FIG. 6, which is a module diagram illustrating the method of the present invention for high-voltage testing of the device under test, wherein the opening degree of the regulating valve is automatically adjusted in a closed-loop manner. As shown in FIG. 6 with reference to FIG. 1, the external gas supply device B provides a gas which first flows to the regulating valve 4, and then to the sensor 3. The sensor 3 measures the pressure and flow rate of the gas and outputs a signal/log record R to the controller 2. The controller 2 automatically adjusts the opening degree of the regulating valve 4. Based on the data in the signal/log record R, such as the gas pressure and flow rate, the controller 2 compares the gas pressure value and the gas flow rate value with the gas pressure set value and the gas flow rate set value respectively, and automatically adjusts the opening degree of the regulating valve 4, to maintain the gas pressure and flow rate within a target range. That is, the gas pressure value is not less than the gas pressure set value, and the gas flow rate value is not greater than the gas flow rate set value. In addition, the controller 2 automatically selects appropriate gas pressure set values and the gas flow rate set values based on the datasets in the built-in table of the controller 2.

Please refer again to FIG. 1, the gas monitoring device D is applied in the high-voltage test system X for testing the device under test A, to monitor and control the gas pressure value and the gas flow rate value of a gas supplied to the probe card assembly 1, and includes:
the controller 2;
the sensor 3 connected with the probe card assembly 1 and electrically connected with the controller 2, to detect the gas pressure value and the gas flow rate value, to generate a pressure signal and a flow rate signal, and to transmit the pressure signal and the flow rate signal to the controller 2;
the regulating valve 4, having an end connected with the sensor 3 and the other end in fluid communication with an external gas supply device B which supplies the gas to the regulating valve 4;
wherein, when the controller 2 interacts with the sensor 3 and thereby detects/determines that the gas pressure value is not less than the gas pressure set value, and the gas flow rate value is not greater than the gas flow rate set value, the controller 2 outputs a control/drive signal to a control unit E of the test system X, enabling the probe card assembly 1 to transmit a high-voltage test signal to perform electrical testing on the device under test A.

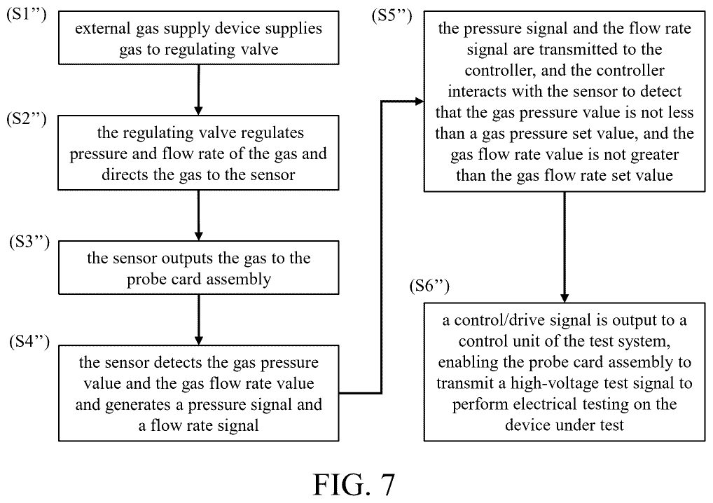

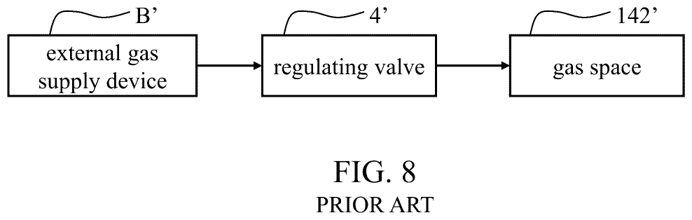

Please refer to FIG. 7, which is a step diagram of the gas monitoring method of the test system for high-voltage testing of the device under test according to the present invention. The gas monitoring method is applied in the test system X for high-voltage testing of the device under test A, to monitor and control the gas pressure value and the gas flow rate value supplied to the probe card assembly 1, and includes the following steps:
(S1″) supplying the gas from the external gas supply device B to the regulating valve 4;
(S2″) regulating a pressure and a flow rate of the gas by the regulating valve 4 and directing the gas to the sensor 3;
(S3″) outputting the gas by the sensor 3 to the probe card assembly 1;
(S4″) detecting the gas pressure value and the gas flow rate value and generating a pressure signal and a flow rate signal by the sensor 3;
(S5″) transmitting the pressure signal and the flow rate signal to the controller 2, and interacting the controller 2 with the sensor 3 to detect/determine that the gas pressure value is not less than a gas pressure set value, and the gas flow rate value is not greater than the gas flow rate set value; and
(S6″) outputting a control/drive signal to a control unit E of the test system X, enabling the probe card assembly 1 to transmit a high-voltage test signal to perform electrical testing on the device under test A.

The test system and test method of the present invention are used for high-voltage testing of a device under test and provide a gas monitoring device and a control unit of the test system, forming a high-voltage testing probe card system with synchronized monitoring functions for both pressure and flow rate. Before the gas enters the gas space of a probe card assembly, a pressure and flow sensor is installed, and cooperates with the gas monitoring device and the control unit of the test system, to construct a complete and closed-loop control mechanism. Therefore, the present invention offers the following advantages:
1. Dual-threshold condition determination: The system starts the high-voltage test only when the gas pressure value is greater than or equal to the gas pressure set value and the gas flow rate value is less than or equal to the gas flow rate set value, to ensure good insulation status within the gas space and stable probe operation;
2. Automatic pressure adjustment and alert mechanism: If the pressure or flow rate does not meet the required standards, the system automatically adjusts the valve to quickly correct the parameters. If the parameters still fail to meet the standards, an alert is triggered or the test is terminated, thereby ensuring the safety of both equipment and personnel; and
3. Adjustable recommended values based on test conditions: The datasets in the built-in table of the controller automatically select corresponding pressure and flow parameters according to test conditions such as the probe pitch, the temperature of the device under test (DUT), and the test voltage, thereby enhancing testing automation and accuracy.

Through the above design, the present invention effectively addresses the issue of insufficient pressure and flow control in the traditional high-voltage testing, and significantly improves the test reliability, precision, and safety. It offers high practicality and innovation for the probe card industry.

At last, it should be mentioned again that the constituent elements disclosed in the above embodiments of the present invention are only taken as examples for illustration, not intended to limit the scope of the present invention. The substitution or variation of other equivalent elements should be included within the scope of the following claims of the present invention.

What is claimed is:

1. A test system for performing high-voltage testing on a device under test, the test system comprising:
a probe card assembly, comprising:
a cover body;
an annular structure having a top surface disposed below the cover body, at least one vent hole in fluid communication with the cover body, a gas space, and a bottom surface configured for facing the device under test; a gas outlet being located below the bottom surface; and
at least one probe electrically connected with the cover body,
accommodated within the gas space, and extending out of the gas space for electrical contact with the device under test during testing;
a gas monitoring device, comprising:
a controller;
a sensor in fluid communication with the cover body and electrically connected with the controller; and
a regulating valve having an end connected with the sensor and the other end in fluid communication with an external gas supply device;
a test apparatus electrically connected with the controller and configured for accommodating the device under test; and
a control unit electrically connected with the gas monitoring device and the test apparatus;
wherein a gas is provided from the external gas supply device, flows through the regulating valve, then to the sensor, and into the cover body, enters the at least one vent hole of the annular structure, then into the gas space, passes through the at least one probe disposed in the gas space, and exits via the gas outlet;
wherein when the controller interacts with the sensor to detect that a gas pressure value detected by the sensor and a gas pressure set value and/or a gas flow rate value detected by the sensor and a gas flow rate set value exhibit a plurality of variation relationships, the probe card assembly, the gas monitoring device, the test apparatus, and the control unit perform corresponding testing operations based on the plurality of variation relationships.

2. The test system as claimed in claim 1, wherein when the controller interacts with the sensor to detect that the following relationship among the plurality of variation relationships exists: the gas pressure value is not less than the gas pressure set value, the controller outputs a signal to the control unit to enable the probe card assembly to transmit a high-voltage test signal to the probe, thereby driving the test apparatus to perform electrical testing on the device under test.

3. The test system as claimed in claim 2, wherein the controller further comprises a built-in table comprising: a tip pitch dataset of the at least one probe, a temperature dataset of the device under test, a high-voltage testing dataset, and a recommended pressure value dataset, wherein the recommended pressure value dataset corresponds to the tip pitch dataset of the at least one probe, the temperature dataset of the device under test, and the high-voltage testing dataset.

4. The test system as claimed in claim 1, wherein when the controller interacts with the sensor to detect that the following relationship among the plurality of variation relationships exists: the gas pressure value is not less than the gas pressure set value, and the gas flow rate value is not greater than the gas flow rate set value, the controller outputs a signal to the control unit to enable the probe card assembly to transmit a high-voltage test signal to the probe, thereby driving the test apparatus to perform electrical testing on the device under test.

5. The test system as claimed in claim 4, wherein the controller further comprises a built-in table comprising: a tip pitch dataset of the at least one probe, a temperature dataset of the device under test, a high-voltage testing dataset, and a recommended pressure and flow rate dataset, wherein the recommended pressure and flow rate dataset corresponds to the tip pitch dataset of the at least one probe, the temperature dataset of the device under test, and the high-voltage testing dataset.

6. The test system as claimed in claim 1, wherein when the controller interacts with the sensor to detect that the following relationship among the plurality of variation relationships exists: the gas pressure value is not greater than the gas pressure set value, the controller executes any one of the following actions:
outputting a signal to generate any one of the following types of alerts: an audible alert, a visual light alert, and a symbolic alert;
adjusting automatically an opening degree of the regulating valve in a closed-loop manner based on the gas pressure value fed back from the sensor, to control the gas pressure within a target range; and
stopping the high-voltage testing of the device under test.

7. The test system as claimed in claim 6, wherein the controller further comprises a built-in table comprising: a tip pitch dataset of the at least one probe, a temperature dataset of the device under test, a high-voltage testing dataset, and a recommended pressure value dataset, wherein the recommended pressure value dataset corresponds to the tip pitch dataset of the at least one probe, the temperature dataset of the device under test, and the high-voltage testing dataset.

8. The test system as claimed in claim 1, wherein when the controller interacts with the sensor to detect that the following relationship among the plurality of variation relationships exists: the gas flow rate value is not less than the gas flow rate set value, the controller executes any one of the following actions:
outputting a signal to generate any one of the following types of alerts: an audible alert, a visual light alert, and a symbolic alert;
adjusting automatically an opening degree of the regulating valve in a closed-loop manner based on the gas flow rate value fed back from the sensor, to control the gas flow rate within a target range; and
stopping the high-voltage testing of the device under test.

9. A test method for performing high-voltage testing on a device under test, the method comprising the following steps:
(SA) providing a gas from an external gas supply device;
(SB) directing the gas to a regulating valve of a gas monitoring device;
(SC) directing the gas to a sensor of the gas monitoring device;
(SD) directing the gas to a cover body of a probe card assembly;
(SE) directing the gas to at least one vent hole of an annular structure of the probe card assembly, wherein a top surface of the annular structure is disposed below the cover body;
(SF) directing the gas to a gas space of the annular structure of the probe card assembly, such that the gas flows through at least one probe disposed in the gas space;
(SG) directing the gas to a gas outlet of the annular structure, such that the gas is discharged from the gas outlet, wherein the gas outlet is located below a bottom surface of the annular structure;
(SH) interacting a controller of the gas monitoring device with the sensor to detect that a gas pressure value and a gas pressure set value and/or a gas flow rate value and a gas flow rate set value exhibit a plurality of variation relationships; and
(SI) performing corresponding testing operations based on the plurality of variation relationships by the probe card assembly, the gas monitoring device, the control unit, and the test apparatus.

10. The test method as claimed in claim 9, wherein the steps (SH) to (SI) further comprise the following steps:
(SH1) interacting the controller with the sensor to detect that the following relationship among the plurality of variation relationships exists: the gas pressure value is not less than the gas pressure set value;
(SI1) outputting a signal from the controller to the control unit; and
(SJ1) enabling the probe card assembly to transmit a high-voltage test signal to the at least one probe, thereby driving the test apparatus to perform electrical testing on the device under test.

11. The test method as claimed in claim 10, wherein the controller further comprises a built-in table comprising: a tip pitch dataset of the at least one probe, a temperature dataset of the device under test, a high-voltage testing dataset, and a recommended pressure value dataset, wherein the recommended pressure value dataset corresponds to the tip pitch dataset of the at least one probe, the temperature dataset of the device under test, and the high-voltage testing dataset.

12. The test method as claimed in claim 9, wherein the steps (SH) to (SI) further comprise the following steps:
(SH2) interacting the controller with the sensor to detect that the following relationship among the plurality of variation relationships exists: the gas pressure value is not less than the gas pressure set value and the gas flow rate value is not greater than the gas flow rate set value;
(SI2) outputting a signal from the controller to the control unit; and
(SJ2) enabling the probe card assembly to transmit a high-voltage test signal to the probe, thereby driving the test apparatus to perform electrical testing on the device under test.

13. The test method as claimed in claim 12, wherein the controller further comprises a built-in table comprising: a tip pitch dataset of the at least one probe, a temperature dataset of the device under test, a high-voltage testing dataset, and a recommended pressure and flow rate dataset, wherein the recommended pressure and flow rate dataset corresponds to the tip pitch dataset of the at least one probe, the temperature dataset of the device under test, and the high-voltage testing dataset.

14. The test method as claimed in claim 9, wherein the steps (SH) to (SI) further comprise the following steps:
(SH3) interacting the controller with the sensor to detect that the following relationship among the plurality of variation relationships exists: the gas pressure value is not greater than the gas pressure set value; and
executing any one of the following actions by the controller:
(SI3) outputting a signal to generate any one of the following types of alerts: an audible alert, a visual light alert, and a symbolic alert;
(SI5) adjusting automatically an opening degree of the regulating valve in a closed-loop manner based on the gas pressure value fed back from the sensor, to control the gas pressure within a target range; and
(SI7) stopping the high-voltage testing of the device under test.

15. The test method as claimed in claim 14, wherein the controller further comprises a built-in table comprising: a tip pitch dataset of the at least one probe, a temperature dataset of the device under test, a high-voltage testing dataset, and a recommended pressure value dataset, wherein the recommended pressure value dataset corresponds to the tip pitch dataset of the at least one probe, the temperature dataset of the device under test, and the high-voltage testing dataset.

16. The test method as claimed in claim 9, wherein the steps (SH) to (SI) further comprise the following steps:
(SH4) interacting the controller with the sensor to detect that the following relationship among the plurality of variation relationships exists: the gas flow rate value is not less than the gas flow rate set value; and
executing any one of the following actions by the controller:
(SI4) outputting a signal to generate any one of the following types of alerts: an audible alert, a visual light alert, and a symbolic alert;
(SI6) adjusting automatically an opening degree of the regulating valve in a closed-loop manner based on the gas flow rate value fed back from the sensor, to control the gas flow rate within a target range; and
(SI8) stopping the high-voltage testing of the device under test.

17. A gas monitoring device applied in a high-voltage test system for testing a device under test, to monitor and control a gas pressure value and a gas flow rate value of a gas supplied to a probe card assembly, the gas monitoring device comprising:
a controller;
a sensor connected with the probe card assembly and electrically connected with the controller, to detect the gas pressure value and the gas flow rate value, to generate a pressure signal and a flow rate signal, and to transmit the pressure signal and the flow rate signal to the controller;
a regulating valve having an end connected with the sensor and the other end in fluid communication with an external gas supply device which supplies the gas to the regulating valve;
wherein, when the controller interacts with the sensor interact to detect that the gas pressure value is not less than a gas pressure set value, and the gas flow rate value is not greater than a gas flow rate set value, the controller outputs a control/drive signal to a control unit of the test system, enabling the probe card assembly to transmit a high-voltage test signal to perform electrical testing on the device under test.

18. A gas monitoring method applied in a test system for high-voltage testing of a device under test, to monitor and control a gas pressure value and a gas flow rate value of a gas supplied to a probe card assembly, the gas monitoring method comprising the following steps:
(SX1) supplying the gas from an external gas supply device to a regulating valve;
(SX2) regulating a pressure and a flow rate of the gas by the regulating valve and directing the gas to a sensor;
(SX3) outputting the gas by the sensor to the probe card assembly;
(SX4) detecting the gas pressure value and the gas flow rate value and generating a pressure signal and a flow rate signal by the sensor;
(SX5) transmitting the pressure signal and the flow rate signal to the controller, and interacting the controller with the sensor to detect that the gas pressure value is not less than a gas pressure set value, and the gas flow rate value is not greater than a gas flow rate set value; and
(SX6) outputting a control/drive signal to a control unit of the test system, enabling the probe card assembly to transmit a high-voltage test signal to perform electrical testing on the device under test.
